(19) United States
(12) Patent Application Publication
(10) Pub. No.: US 2016/0305009 A1
(43) Pub. Date: Oct. 20, 2016

(54) Aperture with Optimized Thermal Emission Behavior

(71) Applicants: China Triumph International Engineering Co., Ltd., Shanghai (CN); CTF Solar GmbH, Dresden (CN)

(72) Inventors: Bastian Siepchen, Dresden (DE); Shou Peng, Shanghai (CN)

(21) Appl. No.: 14/687,934

(22) Filed: Apr. 16, 2015

(51) Int. Cl. C23C 14/24; C23C 14/08

(52) U.S. Cl. CPC C23C 14/243; C23C 14/081

(57) ABSTRACT

An arrangement for the CSS coating of substrates is presented, in which a perforated sheet is arranged between a heated crucible containing a sublimating substance and the substrate to be coated, whereby said perforated sheet has, on the surface facing the crucible and/or the substrate, either a surface structure and/or a coating and/or a covering which increases the thermal emissivity in the direction of the crucible and/or decreases it in the direction of the substrate.

### BACKGROUND

The object of the present invention is an improved perforated sheet between crucible and substrate to be used in the CSS method, which perforated sheet is used particularly in the production of CdTe thin-film solar cells, and semi-finished products for same, and supports, by means of its optimized thermal emission behaviour a more even substrate coating.

In the production of CdTe thin-film solar cells in the state of the art, on a substrate usually of glass, a transparent front contact layer or layer sequence (or TCO, i.e. transparent conducting oxide) is deposited. On this front contact layer, a layer of pure or modified CdS (cadmium sulfide) is deposited and subsequently, on top of this, a layer of CdTe (cadmium telluride) is deposited. Finally the back contact layer, or layer sequence, is added.

In the state of the art, the CdS layer is often deposited according to the CSS (close spaced sublimation) method, in which the glass substrate with the prepared front contact layer is moved in a vacuum over a crucible containing CdS. This crucible is heated, and the material to be deposited (CdS) evaporates (sublimates) from the crucible and precipitates on the front contact layer of the substrate which is kept at a lower temperature than the crucible.

The subsequent deposition of the CdTe layer also takes place preferably using the CSS method.

In the method described, and likewise in the following description, the process steps of cleaning, annealing and sealing according to the state of the art are presumed to be known, and not explained in more detail. The deposition of anti-reflective and protective layers (such as back laminate or glass) is here also presumed to be known.

In the CSS method of CdS deposition the object is to keep the die CdS layer as thin as possible, to restrict a deterioration of the solar cell's optical properties caused by this layer. However, at the same time it must be ensured that the CdS layer does not have any defects (pin holes), which might lead to shunting between the front contact and the CdTe layer. According to the state of the art, to satisfy these two requirements, a layer thickness of 60 nm to 200 nm is preferred.

The CdTe deposition process, too, has as its object a layer having a thickness as uniform as possible. The CdTe layer thickness is preferably 2000 nm to 10000 nm, particularly preferably 3000 nm to 5000 nm.

On an industrial scale, the CdS and CdTe layers are deposited by heating the substrates with the prepared front contact layer (which is facing the direction of the crucibles) and moving them at a constant speed over the crucible opening, resulting in CdS respectively CdTe layers of uniform thickness. In the CSS method, the substrates have a temperature T1, at which the material to be deposited (CdS or CdTe) is deposited on the substrate surface. To ensure that the material can evaporate from the crucible, the temperature in this is temperature T2, at which the material to be deposited will sublimate. This temperature T2 is markedly higher than temperature T1 of the substrate.

According to the state of the art, this process is completed in serially connected, heated vacuum chambers, through which the substrates are moved on a transport system consisting of castors, conveyor belts, or within transport frames, which support the substrates on their lateral edges.

Research has shown that in the CSS method adsorption and desorption of the deposited material strive to attain an equilibrium. This depends on the substrate temperature (or more precisely, on the temperature of the deposited layer). Exact control of the substrate temperature is therefore essential for attaining the desired layer thickness.

However, when moving the substrate over a crucible, the substrate temperature rises steadily due to the thermal radiation emanating from the crucible. This can happen up to the point, at which the precipitation of the material to be deposited is reduced, or even reversed, and therefore the material to be deposited (or the previously deposited layer of material) evaporates again. In the present state of the art, heat must be dissipated through the substrate back (cooling). Resulting from the increasing heating of the substrate surface facing the crucible , varying temperatures arise across different sections of the layer thickness. It is however necessary that the entire layer deposition (from the first nanometres up to the last micrometre) is completed within a narrow temperature range.

Furthermore, within one coating campaign, that is from filling one crucible until the material in the crucible has completely evaporated, the crucible temperature needs to be readjusted to ensure a constant depositing rate (for instance, at the start 640° C., in the end 680° C.). In this connection an unwanted change of the substrate temperature may occur during one coating campaign (due to variation in thermal emission emanating from the crucibles). Therefore the objective is to reduce the thermal coupling between crucible and substrate.

To attain the most evenly spread of the material to be deposited after it has vaporized, often perforated sheets are arranged between crucibles and substrates. The material to be deposited may, after it has vaporized, pass through these perforated sheets, whereby the spread of the material to be deposited becomes more even. To ensure a continuous material passage through the perforated sheet, the sheet is actively being heated, to avoid condensation of material. This heating is preferably carried out by means of an electric resistance heating, either directly or indirectly. In HÄDRICH, chapter 4, pp. 25-27 the properties of the perforated sheet, the CSS method and the running processes are explained in more detail.

Under point 4.2, p. 28 HÄDRICH explains: “a substantial modification . . . is the use of a 3 mm thick glass substrate coated with FTO (SnO 2:F), to which [glass substrate] the temperature profile needs to be adjusted during deposition, in order to avoid re-evaporization of the CdS layer due to excessive heating.”

It has evidently been noted in the relevant literature that excessive thermal heating of the substrate (more precisely, of the materials already deposited) may prove problematic in the CSS method.

Therefore the object is to reduce the thermal heating of the substrate over the crucible in the CSS method.

According to the invention, the object is achieved with the device according to claim 1. Advantageous embodiments of the device are disclosed in the corresponding dependent sub-claims.

According to the state of the at, the perforated sheets are flat and even-surfaced and are arranged between crucible opening and substrate, and in parallel to the latter. Recently used perforated sheets are made from homogeneous metal (e.g. graphite, molybdenum). The thickness of the perforated sheets is in the range of 3 mm to 10 mm, preferably c. 5 mm. The holes are either evenly spread across the perforated sheet, or else in line with a pattern improving the coating homogeneity. Details for arrangements and measurements of the holes, and the necessary calculations for designing them are also found in HÄDRICH. Characteristically, the number of holes usually increases on the edge of the perforated sheet, because most of the substance evaporates in the centre of the crucible, which needs to be compensated by a higher number of holes in the edge area. However, besides the number of holes in the perforated sheet, also the size of hole diameters may be varied. The perforated sheets in the state of the art have the same thermal properties with regard to all spatial directions (i.e. both in the direction of the substrate and in the direction of the crucible), especially the same thermal emission properties.

### SUMMARY

An arrangement for the CSS coating of substrates is presented, in which a perforated sheet is arranged between a heated crucible containing a sublimating substance and the substrate to be coated, whereby said perforated sheet has, on the surface facing the crucible and/or the substrate, either a surface structure and/or a coating and/or a covering which increases the thermal emissivity in the direction of the crucible and/or decreases it in the direction of the substrate.

### DETAILED DESCRIPTION

In the arrangement according to the invention it is intended to arrange the substrates above perforated sheets which have direction-dependent thermal properties. In particular, the perforated sheets are required to have a lesser thermal emission capacity in the direction of the substrate than in the direction of the crucible. The hole dimensions and arrangements known from prior art may be used.

The varying thermal emission capacity is attained using differing materials, or alternatively using differing material properties (surface structure) on that surface of the perforated sheet which faces the crucible and/or the substrate. The thermal emission capacity is determined as thermal emissivity (here: emissivity). For measuring the thermal emissivity, methods according to the state of the art are used. For example, pyrometers (thermopiles), bolometers or quantum detectors are used.

In a first preferred embodiment, the surface of the perforated sheet facing the crucible has a roughened surface structure, whereas the surface facing the substrate is smooth or even polished. The roughened texture may be created e.g. by sand blasting.

In a further preferred embodiment, the surface of the perforated sheet facing the crucible is coated with a material having a higher emissivity than the material of the perforated sheet.

In yet another preferred embodiment, the surface of the perforated sheet facing the crucible is coated with a material having a lower emissivity than the material of the perforated sheet.

In a further preferred embodiment, it is intended that the surface of the perforated sheet facing the crucible is coated with a material having a higher emissivity, and the surface of the perforated sheet facing the substrate is coated with a material having a lower emissivity than the material of the perforated sheet.

In the preferred embodiments, it is intended that the perforated sheet is produced in a multi-layered manner, preferably double-layered or triple-layered, whereby the material having the lowest emissivity is facing the substrate. To reduce the heat passage through the perforated sheet, advantageous modifications have a clearance between at least two of these layers, or alternatively have an arrangement of heat insulating material between at least two of these layers.

The measures mentioned above to increase the degree of thermal emission on the surface facing the crucible may be combined with measures to decrease the degree of thermal emission on the surface facing the substrate, or the other way round, according to the technical requirements.

Data on the degrees of thermal emission may be gathered from publicly available works of reference and databases. The methods of measuring in the state of the art are likewise documented.

In a preferred embodiment, the perforated sheet consists of graphite having a thickness preferably in the range of 3 mm to 10 mm, more preferably of 4 mm to 8 mm and particularly preferably of 5 mm to 7 mm.

Coatings with materials which have degrees of emission differing from that of the material of the perforated sheet, are preferably in the thickness range of 100 nm to 0.1 mm, more preferably in the range of 150 nm to 50 pm and particularly preferably in the range from 300 nm to 10 μm. In the direction of the crucible, the coating may be executed as a blackening (SiC, graphite). In the direction of the substrate, the coating may be executed as a brightening (Al₂O₃) or reflective coating. Materials suitable for the coatings do not contaminate the process. These are often oxidic or ceramic materials having an innate roughness. Preferably, these materials are Al₂O₃, SiC or pyrolytic graphite.

In a further preferred embodiment, the perforated sheet is executed in graphite having the material thickness mentioned above and, in the direction of the substrate, it is provided with a flat sheet metal which has openings corresponding to the perforated sheet. The sheet metal is preferably made from molybdenum and preferably has a thickness between 0.05 mm and 1.5 mm, more preferably between 0.075 and 1.25 mm, and particularly preferably between 0.1 mm to 1 mm. In a preferred embodiment the openings of the sheet metal are bigger than those of the perforated sheet. This has the advantage of preventing overgrowth of the openings due to coating material which has precipitated on the sheet metal. Further preferred in this connection is the (direct or indirect) heating of the sheet metal. In another preferred embodiment there is a clearance (1 mm to 3 mm) between the perforated sheet and the sheet metal, in which case the perforated sheet and/or the sheet metal have local spacers, which ensure that a constant space is kept between perforated sheet and sheet metal. In a preferred embodiment, these spacing elements are intended to form raised edges around the openings. The advantage here consists in particular in the fact that around the openings a heat-conducting contact is ensured which causes the temperature of the sheet metal, especially in the area around the openings, to approximate that of the perforated sheet. This helps avoid precipitation of coating material around the sheet metal openings. A further modification of this embodiment includes a heat insulation material in the clearance. Suitable heat insulation material include for example carbon or glass fibres. The thus formed multi-layered perforated sheet has an advantageously reduced heat passage.

### BRIEF DESCRIPTION OF THE DRAWINGS

FIG. 1 schematically shows the arrangement of an embodiment of the perforated sheet according to the invention, over the crucible (3) with granular material to be deposited (31). The perforated sheet (2) here consists of the perforated sheet proper (2) and the sheet metal (21) arranged above said sheet, which is separated by the perforated sheet proper (2) by a space (22). Above the perforated sheet (2) the deposited material (33), evenly spread in its spatial distribution, is shown. Subsequently said material is deposited on the lower surface of the substrate (1), which is steadily being moved in the direction of movement of the substrate (11).

FIG. 2a schematically shows a perforated sheet (2) according to the invention, having a coating (24) on the surface facing the substrate, which coating has a lower degree of thermal emission than the uncoated surface facing the crucible of the perforated sheet (2).

FIG. 2b schematically shows a perforated sheet (2) according to the invention, having a coating (25) on the surface facing the crucible, which coating has a higher degree of thermal emission than the uncoated surface facing the substrate of the perforated sheet (2).

FIG. 2c schematically shows a perforated sheet (2) according to the invention, having both a coating (24) on the surface facing the substrate and a coating (25) on the surface facing the crucible. The coating (24) on the surface facing the substrate has a lower degree of thermal emission than the uncoated material of the perforated sheet (2), whereas the coating (25) on the surface facing the crucible has a higher degree of thermal emission than the uncoated material of the perforated sheet (2).

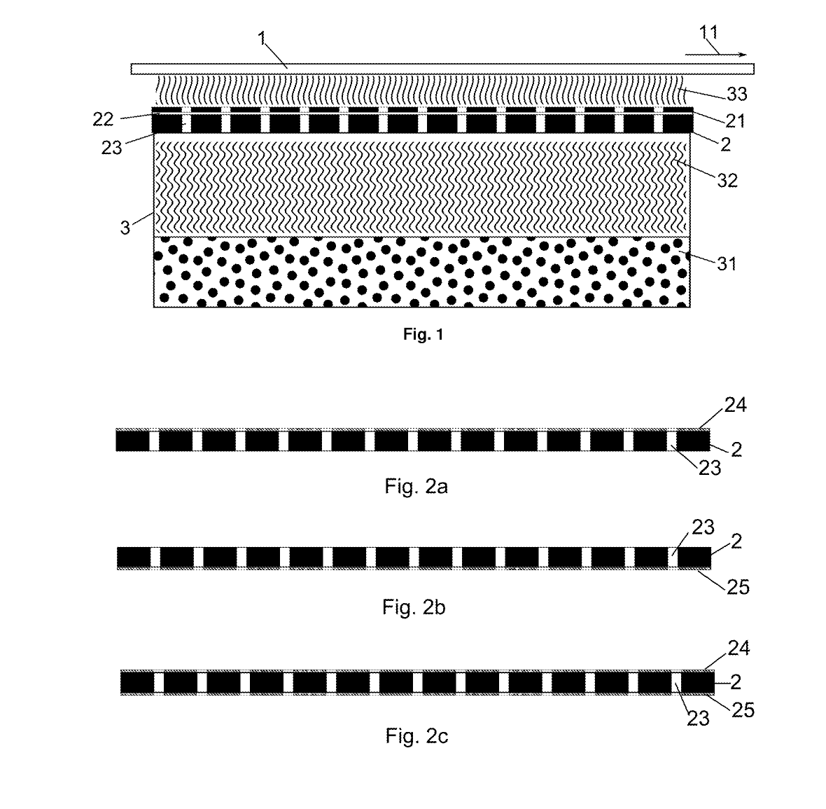

### DETAILED DESCRIPTION OF THE PREFERRED EMBODIMENTS

On a substrate (1) having the dimensions (1600 mm×1200 mm×3.2 mm) a coating made of indium-tin-oxide (ITO) with a thickness of 250 nm is applied as a transparent front contact layer.

Afterwards the substrate (1) with its front contact layer pointing downwards, is fed into a sequence of vacuum chambers, or alternatively into one continuous vacuum chamber having different sections. The substrate is heated to a temperature of 500° C. in the first vacuum chamber (or the first section thereof). Heating is carried out by means of suitable heating devices, while the substrate (1), resting on a transport device (not shown) is moved by this device through the first vacuum chamber (respectively the first section thereof). The substrate reaches the next vacuum chamber (respectively the next section) and continues to be moved by the transport device (at a speed of 1.5 m/min) and at a distance of 0.5 cm, over a crucible (3) with CdS granulate (31). The crucible (3) extends over the entire breadth (perpendicular to the direction of transport (11)) of the substrate (1) and extends in the direction of transport (11) over a length of 17 cm. The CdS (31) in the crucible (3) has been heated to 620° C. and sublimated. The evaporating gases (32) pass through a perforated sheet (22) with a thickness of 6 mm and are deposited on the front contact layer of the substrate (1). While the rising gaseous CdS (32) is passing through the openings (23) of the perforated sheet (2) the CdS becomes more evenly spatially distributed above the perforated sheet (2). The perforated sheet (2) consists of graphite with a thickness of 5 mm and has circular openings (23) with a diameter of 3 mm. On the surface facing the crucible, the perforated sheet (2) is roughened. The surface facing the substrate has a sheet metal made of molybdenum (21) of 1 mm thickness which sheet metal has openings corresponding to those in the perforated sheet (2). Due to the molybdenum sheet metal (21) the heated perforated sheet (2) does not directly emit heat onto the substrate (1). The molybdenum sheet metal (21) situated between perforated sheet (2) and substrate (1) shields the substrate. Since the underside of the perforated sheet (2) is roughened, the preferred thermal emission from the perforated sheet (2) is directed back towards the crucible (3). The topside of the graphite part of the perforated sheet (2) is smooth, and for that reason alone it transmits less heat to the molybdenum sheet metal (21) arranged above it.

During regular refilling of the CdS granulate in the crucibles, the perforated sheet (2) which rests on the crucibles and is removable is also cleaned and cleared of any deposits.

When the substrate (1) has passed the crucible (3), the front contact layer has a complete (except at the points of contact), homogeneous layer of CdS (not shown) with a thickness of 65 nm. After applying this CdS layer, the substrate (1) is further processed according to the state of the art. To this effect, the substrate (1) is transported at a temperature of 500° C. into the subsequent treatment chambers. At this point the CdTe layer with a thickness of 5000 nm is applied, also using the CSS method and using the perforated sheet (2) according to the invention. Afterwards the back contact layer, or layers, are applied using methods according to the state of the art. The back contact layer here consists of a layer sequence of adaptation layer and the contact layer proper. Here, an adaptation layer made from Te (50 nm) is formed by means of nitric-phosphoric acid etching of the CdTe layer, and on to this, subsequently the layer of Mo (250 nm) is deposited as the contact layer proper.

Finally, the remaining process steps are completed according to the state of the art.

### CITED NON-PATENT LITERATURE

Mathias HÄDRICH, “Materialwissenschaftliche Untersuchungen an CdTe—CdS-Heterosolarzellen” [Analysis of CdTE heterojunction solar cells relating to Materials Science], PhD, Friedrich-Schiller-Universität Jena, 2009; see http://www.db-thueringen.de/servlets/DerivateServlet/Derivate-18406/H%C3%A4drich/Dissertation.pdf (link accessed 26.11.2013)

### LIST OF REFERENCE NUMERALS

1 Substrate (Glass)
11 Direction of movement of substrate
2 Perforated sheet
21 Sheet metal
22 Space between perforated sheet and sheet metal
23 Opening in perforated sheet
24 Coating on the substrate surface of perforated sheet
25 Coating on the crucible surface of perforated sheet
3 Crucible
31 Granular material to be deposited
32 Sublimated material to be deposited rising from granulate
33 Sublimated material to be deposited after passing through perforated sheet

1. An arrangement for the CSS coating of substrates, having a heated crucible with a sublimating material and an opening which is directed towards a substrate to be coated, which substrate is arranged in front of, or passing, said opening, whereby between the substrate and the crucible opening, and covering the entire crucible opening, a perforated sheet with openings is arranged, characterized in that the perforated sheet has, on the surface facing the crucible and/or the substrate, a surface structure and/or coating and/or covering which increases the thermal emissivity in the direction of the crucible and/or decreases it in the direction of the substrate, when compared to a perforated sheet without any surface structure and/or coating and/or covering.

2. The arrangement for the CSS coating of substrates according to claim 1, characterized in that the surface structure consists in a roughened surface of the surface facing the crucible of the perforated sheet.

3. The arrangement for the CSS coating of substrates according to claim 1, characterized in that the coating consists of a blackened surface of the surface facing the crucible of the perforated sheet.

4. The arrangement for the CSS coating of substrates according to claim 1, characterized in that the coating consists of the arrangement of a sheet metal cover having openings corresponding to that of the perforated sheet on the surface facing the crucible of the perforated sheet.

5. The arrangement for the CSS coating of substrates according to claim 1, characterized in that the surface structure consists in a polished surface of the surface facing the substrate of the perforated sheet.

6. The arrangement for the CSS coating of substrates according to claim 1, characterized in that the coating consists of a bright coating, containing Al₂O₃, or a reflective coating on the surface facing the substrate of the perforated sheet.

7. The arrangement for the CSS coating of substrates according to claim 1, characterized in that the coating consists in the arrangement of a sheet metal cover having openings corresponding to that of the perforated sheet on the surface facing the substrate of the perforated sheet.

8. The arrangement for the CSS coating of substrates according to claim 4, characterized in that there is a clearance between cover and perforated sheet.

9. The arrangement for the CSS coating of substrates according to claim 8, characterized in that said clearance is filled with heat insulating material, excepting the areas of the openings as well as the perforated sheet and cover.

10. The arrangement for the CSS coating of substrates according to claim 9, characterized in that said heat insulating material consists of carbon fibre or glass fibre.
